(19) United States
(12) Patent Application Publication
(10) Pub. No.: US 2026/0121529 A1
(43) Pub. Date: Apr. 30, 2026

(54) POWER CONVERSION

(71) Applicant: Cirrus Logic International Semiconductor Ltd., Edinburgh (GB)

(72) Inventors: Angus BLACK, Largs (GB); Jose DUARTE, Edinburgh (GB)

(73) Assignee: Cirrus Logic International Semiconductor Ltd., Edinburgh (GB)

(21) Appl. No.: 18/989,144

(22) Filed: Dec. 20, 2024

Related U.S. Application Data
(60) Provisional application No. 63/622,625, filed on Jan. 19, 2024.

(51) Int. Cl. H02M 3/04; H03K 3/017

(52) U.S. Cl. CPC H02M 3/04; H03K 3/017

(57) ABSTRACT

A power converter system, comprising: a main device; one or more secondary devices, each comprising: one or more switching converters; and a signal generator configured to generate a modulated signal for controlling the one or more switching converters, wherein a period of the modulated signal is pseudo-randomly adjusted within a predetermined period range; and a data bus comprising a data line for data transmission between the main device and the plurality of secondary devices, and a clock line for transmitting an interface clock signal; wherein the main device is configured to transmit a synchronization frame to the plurality of secondary devices; wherein each of the one or more secondary devices is configured to time align generation of the modulated signal in dependence on the synchronization frame.

### TECHNICAL FIELD

The present disclosure relates to methods and apparatus for synchronizing switching of distributed switching converters over a data bus.

### BACKGROUND

Communication buses, such as serial communication busses comprising a clock line and a data line, are commonly used for synchronous data transfer between integrated circuits (ICs). Such solutions allow a main (or control) device or module to communicate with multiple secondary (or responder) devices over the shared data line.

A switching power converter is typically controlled using a modulated signal, such as a pulse-width modulated (PWM) signal having a fixed switching frequency. In some circumstances, it may be desirable to spread the spectrum of the modulated signal to reduce the impact of electromagnetic interference arising from switching at a fixed switching frequency. When multiple switching power converters are provided in a single system, independent, unsynchronized variation of switching frequency of those switching converters can lead to increased ripple in current supplied to such converters.

### SUMMARY

According to a first aspect of the disclosure, there is provided a power converter system, comprising: a main device; one or more secondary devices, each comprising: one or more switching converters; and a signal generator configured to generate a modulated signal for controlling the one or more switching converters, wherein a period of the modulated signal is pseudo-randomly adjusted within a predetermined period range; and a data bus comprising a data line for data transmission between the main device and the plurality of secondary devices, and a clock line for transmitting an interface clock signal; wherein the main device is configured to transmit a synchronization frame to the plurality of secondary devices; wherein each of the one or more secondary devices is configured to time align generation of the modulated signal in dependence on the synchronization frame.

The modulated signal may be a pulse width modulated, PWM, signal, wherein the period is a switching period of the PWM signal.

Each signal generator may be configured to generate a PWM ramp signal, the PWM signal is generated based on the PWM ramp signal, and the signal generator may be configured to pseudo-randomly vary a peak amplitude of the ramp signal within a predetermined peak range.

The PWM ramp signal may comprise a triangular ramp or a sawtooth ramp.

An amplitude of the PWM ramp signal may be increased during a ramp-up phase in steps at a quantization clock frequency. The signal generator may be configured to pseudo-randomly vary the duration of the ramp-up phase.

The quantization clock frequency may be greater than a frequency of the interface clock.

The signal generator may comprise a comparator, comprising: a first input for receiving the PWM ramp signal; a second input for receiving a PWM control signal; and an output for outputting the PWM signal.

The synchronization frame may comprise one or more synchronization bits, wherein each of the one or more secondary devices is configured to time align generation of the modulated signal in dependence on receipt of the one or more synchronization bits.

Each of the one or more secondary devices may be configured to time align generation of the modulated signal in response to receipt of the synchronization frame.

Each signal generator may comprise: a pseudorandom number generator clocked by the interface clock signal, the pseudorandom number generator configured to generate a pseudorandom number.

Each signal generator may be configured to synchronously reset its respective pseudorandom number generator in response to receipt of synchronization data in the synchronization frame.

The pseudorandom number generator may comprise a linear feedback shift register, LFSR.

The signal generator may be configured to pseudo-randomly vary a period of the modulated signal based on the pseudorandom number.

The one or more secondary device may comprise a plurality of secondary devices, wherein respective pseudorandom number generators of the plurality of secondary devices are configured to output an identical sequence of pseudorandom numbers.

The respective pseudorandom number generators of the plurality of secondary devices may be substantially identical.

The main device may comprise: one or more main switching converters; and main signal generator configured to generate a main modulated signal for controlling the one or more main switching converters, wherein a period of the main modulated signal is pseudo-randomly adjusted within a predetermined period range, wherein the main signal generator comprises a main pseudorandom number generator, wherein the main pseudorandom number generator is configured to output an identical sequence of pseudorandom numbers to the pseudorandom number generators of each of the one or more secondary devices.

The main device may comprise: a main pseudorandom number generator, the main pseudorandom number generator configured to output an identical sequence of main pseudorandom numbers to the pseudorandom number generators of each of the one or more secondary devices.

A length of the synchronization frame may be set based on the main pseudorandom number.

The main device may comprise: one or more main switching converters; and a main signal generator configured to generate a main modulated signal for controlling the one or more main switching converters, wherein a period of the main modulated signal is pseudo-randomly adjusted within a predetermined period range.

A length of the synchronization frame may be pseudo-randomly adjusted.

The synchronization frame may comprise one or more target current bits, wherein the signal generator is configured to modulate the modulated signal based on the one or more target current bits.

The synchronization frame may comprise one or more phase mode bits, wherein based on the one or more mode bits, the signal generator is configured to activate or deactivate the one or more switching converters and/or adapt a phase of the modulated signal.

The synchronization frame may comprise one or more error detecting bits.

The data bus may be a serial data bus or a two-wire bus.

According to another aspect of the disclosure, there is provided a main device configured to communication with a plurality of secondary devices via a data bus comprising a data line and a clock line; wherein the main device is configured to communicate with each of the plurality of secondary devices using a unique secondary address associated with each respective secondary device, wherein the main device is transmit a synchronization frame to the plurality of secondary devices, the synchronization frame used by each of the one or more secondary devices to time align generation of the modulated signal in dependence on the synchronization frame.

The main device may be an application processor.

According to another aspect of the disclosure, there is provided a secondary device configured to communicate with a main device via a data bus comprising a data line and a clock line, the secondary device comprising: one or more secondary devices, each comprising: one or more switching converters; and a signal generator configured to generate a modulated signal for controlling the one or more switching converters, wherein a period of the modulated signal is pseudo-randomly adjusted within a predetermined period range; the secondary device configured to: receive, over the data line, a synchronization frame; and time align generation of the modulated signal in dependence on the synchronization frame.

According to another aspect of the disclosure, there is provided a device comprising: a data bus; the main device described above; and the secondary device described above.

According to another aspect of the disclosure, there is provided an electronic device, comprising the power converter system described above. The electronic device may comprise one of a mobile computing device, a laptop computer, a tablet computer, a games console, a remote-control device, a home automation controller or a domestic appliance, a toy, a robot, an audio player, a video player, or a mobile telephone, and a smartphone.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 is a schematic diagram of a two-wire bus architecture according to an embodiment of the present disclosure;

FIG. 2 is a schematic diagram of an example implementation of a device connected to the bus shown in FIG. 1;

FIG. 3 is a schematic diagram of an example implementation of the modulator shown in FIG. 2;

FIGS. 4 and 5 are schematic illustrations of example ramp signals generated by the ramp generator of the modulator shown in FIG. 3;

FIG. 6 is a diagram of an example synchronization frame;

FIG. 7 is a timing diagram for an example transmission over the bus of FIG. 1; and

FIGS. 8 and 9 graphically compare the spectrum of the modulated signal generated by the modulator of the device of FIG. 2 without and with spectral spreading.

### DESCRIPTION OF EMBODIMENTS

A switching power converter is typically controlled using a modulated signal, such as a pulse-width modulated (PWM) signal having a fixed switching frequency. In some circumstances, it may be desirable to spread the spectrum of the modulated signal to reduce the impact of electromagnetic interference arising from switching at a fixed switching frequency. When multiple switching power converters are provided in a single system, independent, unsynchronized variation of switching frequency of those switching converters can lead to increased ripple in supply current required by such converters, and increased ripple in voltages obtained from such converters.

Embodiments of the present disclosure aim to address or at least ameliorate one or more of the above issues by providing a serial data communications protocol for synchronizing variations in frequency of modulated signals used to drive switching converters in multiple separate devices. A main device is configured to communicate, via a serial data bus, a synchronization frame comprising synchronization data to one or more secondary devices. Such secondary devices, each comprising a switching converter, may then be configured to time align or synchronization variations in frequency of respective modulated signals used to control a respective to which variation in frequency (or period) of respective modulated signals used to drive respective switching converters. By time aligning frequency spreading of modulated signals, the electromagnetic interference (EMI) may be reduced whilst minimizing current ripple otherwise associated with unsynchronized switching of multiple converters.

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

FIG. 1 is a schematic diagram of a two-wire serial bus architecture 100. The serial bus 101 comprises a clock line 102 and a data line 104. A main device 106, (also known in the art as a control device, or primary device, or a host device) communicates with a plurality of secondary devices 108, 110, 112 (also known in the art as responder devices or peripheral devices) over the data line 104. In the example shown, a single main device 106 is provided. However, in practice, more than one main device can be provided. In the example shown, three secondary devices are provided. However, in practice, any number N of secondary devices may be connected to the clock and data lines 102, 104. To send data to one of the secondary devices 108, 110, 112, the main device 106 may transmit a data frame over the data line 104 comprising bytes of data.

The main device 106 and the plurality of secondary devices 108, 110, 112 may share several similar features. The main device 106 may differ from the plurality of secondary devices 108, 110, 112 only in that the main device may be configured to transmit control data over the data line 104, whereas the secondary devices 108, 110, 112 are configured to received control data over the data line 104. It will be appreciated that in some embodiments, the main device 106 and the secondary device 108, 110, 112 may be substantially identical. For example, each of the secondary devices 108, 110, 112 may be configurable as the main device 106, and vice versa.

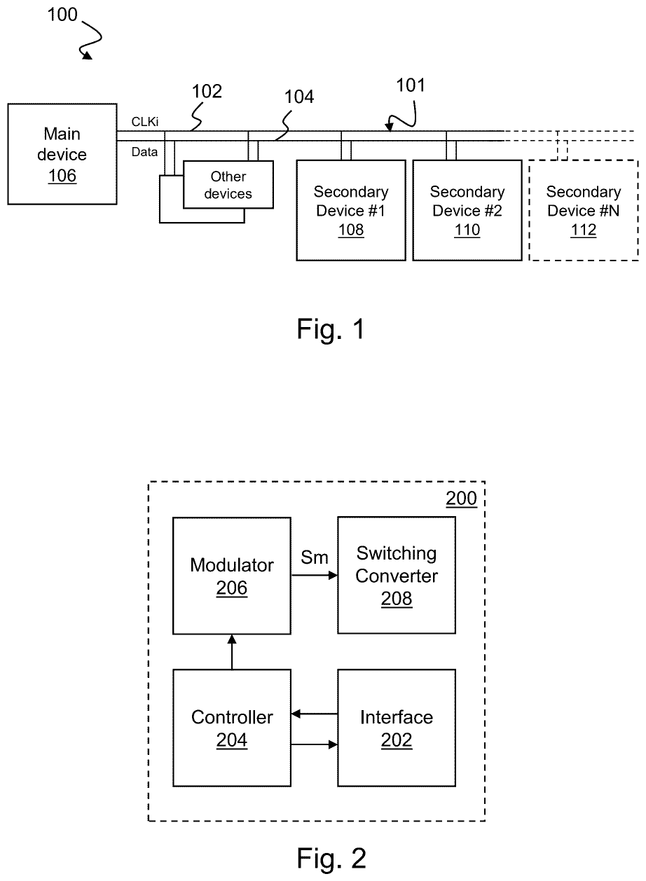

FIG. 2 is a schematic diagram of an example implementation of a device 200 which may be any one of the secondary devices 108, 110, 112 or the main device 106.

The device 200 comprises an interface 202, a controller 204, a modulator 206 and a switching converter 208. The device 200 may comprise additional switching converters (not shown).

The device 200 may comprise an audio device comprising one or more audio amplifiers. Such an audio device may be used in a home audio system or a vehicle audio system. As such, the main device 106 and one or more secondary devices 108, 110, 112 may represent multiple audio devices distributed over a network, e.g. throughout a home or distributed across a vehicle.

The interface 202 is operable to communicate with other devices, such as the main device 106 or the secondary devices 108, 110, 112 over a bus 101, such as the architecture 100 shown in FIG. 1. When the device 200 is configured as one of the secondary devices 108, 110, 112, the interface 202 may be configured to receive and process (e.g. decode) data frames transmitted over the bus 101. The interface 202 may then pass processed (decoded) data to the controller 204. When configured as a main device, the interface may be configured to construct and transmit one or more data frames over the bus, for example based on data received from the controller 204.

The controller 204 is configured to control the modulator 206. When configured as a secondary device, the controller 204 may be configured to control the modulator 206 based on data received via the interface 202 from the bus. When configured as the main device 106, the controller 204 may be configured to independently control the modulator 206, in addition to outputting data to the interface 202 for encoding into a data frame to be transmitted by the interface 202.

The modulator 206 is configured to generate a modulated signal Sm which is provided to the switching converter 208 for control of switches of the switching converter 208. The modulated signal Sm may be a pulse-width modulated (PWM) signal. As will be discussed in detail below, a period of the modulated signal Sm is adjusted pseudo-randomly based in accordance with a predetermined pseudo-random sequence generated by pseudo-random number generator provided as part of the modulator 206, the controller 204, or provided separately on the device 200.

The switching converter 208 may be a boost converter, a buck converter, or a buck boost converter. Switches of the switching converter 208 are controlled by the modulated signal Sm received from the modulator 206. Where the modulated signal Sm is a PWM signal, the pulse width of the modulated signal Sm may be varied by the modulator 206 to control conversion by the switching converter 208. PWM control of switching converters is known in the art and so will not be discussed further here.

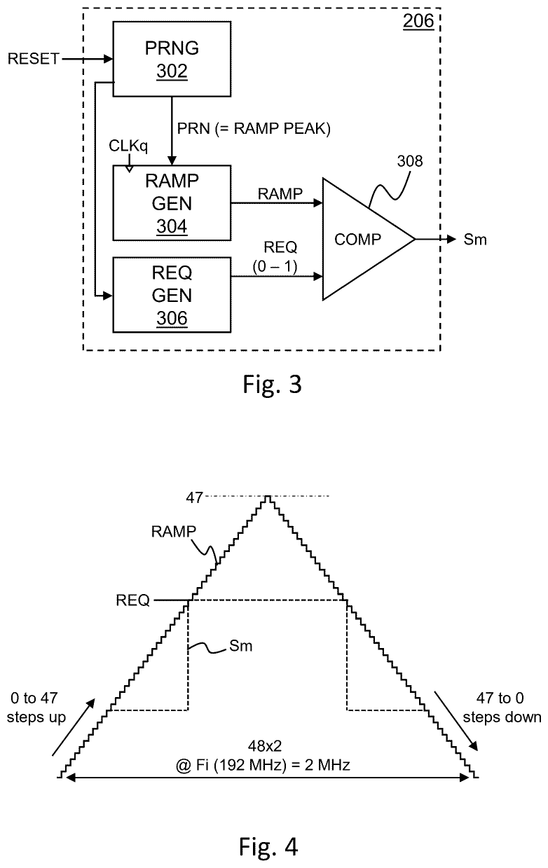

FIG. 3 is a schematic diagram of an example implementation of the modulator 206, configured for generation of a PWM modulated signal Sm, a period of which is varied pseudo-randomly within a predetermined threshold range. In this example, the modulator comprises a pseudo-random number generator 302, a ramp generator 304, a request signal generator 306, and a comparator 308.

The pseudo-random number generator (PRNG) 302 may be configured as a linear feedback shift register. The PRNG 302 may be configured to output a pseudo-random number PRN to the ramp generator 304 and optionally to the request signal generator 306. The PRN may be a two-bit code, as will be described in more detail below. The PRNG 302 may be clocked by an interface clock CLK. The PRNG 302 may be used to define a length and peak of a ramp signal RAMP. The PRNG 302 may also be used to define a level of a request signal REQ.

The ramp generator 304 is configured to generate the ramp signal RAMP in dependence on which a PWM signal Sm may be generated. Using ramp signals to generate PWM signals is known in the art. In this example, the ramp signal RAMP is triangular (ramp up, ramp down). In other embodiments, the ramp signal RAMP may be implemented as a rising-ramp reference.

The request signal generator 306 is configured to generate a request signal REQ. The request signal REQ may be scaled based on the PRNG 302 to take into account changes in overall period of the PWM signal Sm, as will be described in more detail below.

An example of the ramp signal RAMP generated by the ramp generator 304 is shown in FIG. 4. The ramp generator 304 is clocked by a quantization clock CLK at an internal clock frequency Fi, in this example 192 MHz. During a ramp-up phase, the ramp generator 304 is configured to apply a stepwise increase in the amplitude of the ramp signal RAMP at the internal clock frequency Fi, i.e. in response to a positive or negative transition of the quantization clock CLK. The ramp-up phase lasts for a duration of 48 clock periods of the internal clock CLK. The ramp signal RAMP amplitude increases in 48 clock cycles from 0 to 47. At this point, during a ramp-down phase, the ramp generator 304 is configured to apply a stepwise decrease in the amplitude of the ramp signal RAMP at the internal clock frequency Fi. The ramp-down phase lasts for a duration of 48 clock periods of the internal clock CLK, i.e. until the ramp signal RAMP has returned to zero. The ramp generator 304 repeats the ramp-up and ramp down phase to generate the triangular (ramp-up, ramp-down) ramp signal RAMP.

It will be appreciated that the ramp is described here in relative values (0 to 47) which may relate to any conceivable relative voltages. By way of non-limiting example, 0 may refer to ground and 47 to 2 V.

The ramp signal RAMP is provided to the comparator 308 which is configured to compare the ramp signal RAMP to a PWM request signal REQ generated by the request signal generator 306. As depicted in FIG. 4, when an amplitude of the ramp signal RAMP exceeds an amplitude of the request signal REQ, the PWM signal Sm goes high. When the amplitude of the request signal REQ exceeds an amplitude of the ramp signal RAMP, the PWM signal Sm goes low. Thus, the amplitude of the request signal REQ sets the pulse width of the PWM signal Sm and is thus used to encode the PWM signal Sm for switching of the switching converter(s) 208.

To vary the period of the PWM signal Sm, the ramp generator 304 may be configured to adjust the duration of the ramp-up phase and ramp-down phase. For example, with reference to FIG. 4, if the ramp-up and ramp-down phases were reduced to from 48 to 46 clock periods each, the ramp signal RAMP would increase in 46 clock cycles from 0 to 45 and decrease in 46 clock signals from 45 to 0. Thus, the overall period of the PWM signal Sm is decreased.

Adjustment of PWM signal Sm period may be based on the PRN output from the PRNG, such that the period of the PWM signal Sm is pseudo-randomly varied.

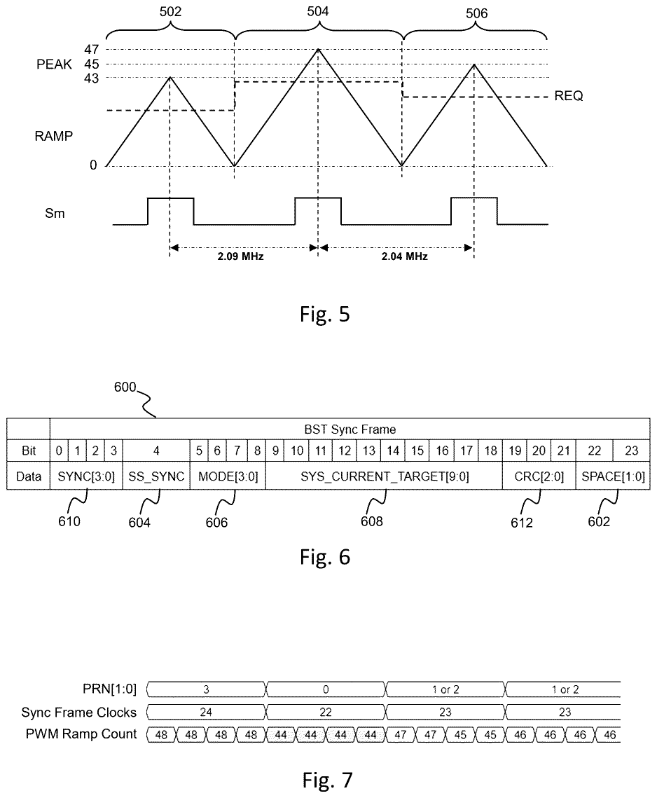

FIG. 5 illustrates a timing diagram for an example implementation of this pseudo-random variation of the PWM signal Sm based on the ramp signal RAMP. Three cycles 502, 504, 506 of the ramp signal RAMP are depicted alongside respective cycles of the PWM signal Sm and the PWM request signal REQ.

It can be seen that the ramp peak PEAK of the three cycles 502, 504, 507 differs causing the period between successive pulses in the PWM signal Sm to vary overtime. The frequency between of the first and second cycles 502, 504 is 2.09 MHz, whereas the frequency between the second and third cycles 504, 506 is 2.04 MHz. The ramp peak PEAK of each cycle 502, 504, 506 is controlled by the modulator 206 based on the PRN from the PRNG 302 such that the mean frequency of the PWM signal Sm is 2.09 MHz, but the spectrum of the PWM signal Sm is spread across a range of frequencies due to the pseudo-random variation of the ramp peak PEAK.

Thus, to mitigate the effects of an EMI generated by the switching converter(s) 208 operating at a single switching frequency, the characteristics of the PWM signal Sm can be adjusted, e.g. a switching period of the PWM signal varied, preferably in a random or pseudo-random manner, to distribute the switching frequency of the switching converter 208, thereby spreading the spectrum of the switching frequency of the converter, to reduce the EMI effect of operation of the converter 208.

A byproduct of varying the ramp peak PEAK is that the time at which the ramp signal RAMP is above a certain threshold level also varies. Accordingly, holding the PWM request signal REQ constant over successive cycles of the ramp signal RAMP would itself lead to modulation of the duty cycle of the PWM signal Sm. To mitigate this, the request signal generator 306 is configured to adjust the PWM request signal REQ such that the duty cycle of the PWM signal Sm is not affected by adjustment of the ramp peak PEAK. It can be seen from FIG. 5 that a variation in the PWM request signal REQ maintains the duty cycle between successive pulses of the PWM signal Sm constant, despite the period between pulses changing. The request signal generator 306 may be configured to vary the request signal REQ based on the PRN output from the PRNG 302, or in response to a signal (not shown) from the ramp generator 304.

Referring again to FIG. 1, the system 100 comprises a main device 106 and at least one secondary device 108, 110, 112. In such systems, each of the devices 106, 108, 110, 112 may dynamically adjust the operation of their respective modulators 206 independently of the other devices, i.e. each of the devices 106, 108, 110, 112 independently varying ramp peak PEAK and cycle length based on respective PRNs. However, such operation may result in undesirable total input current ripple from the combination of input current to each switching converter 208.

To address or at least ameliorate undesirable input ripple whilst also mitigating EMI through spread spectrum switching, embodiments of the present disclosure aim to synchronize operation of switching converters 208 across multiple devices 106, 108, 110, 112.

As noted above, the main device 106, which may be a specific implementation of the device 200 shown in FIG. 2, may be configured to transmit synchronization frames to allow for synchronization between the main device 108 and the one or more secondary devices 108, 110, 112. By synchronizing converter operation over multiple devices, in addition to mitigating output ripple during spread spectrum operation as described above, inductive current demand from different devices can be controlled so as to have advantageous phase relationships. For example, if two phases are enabled with 180-degree separation and each has approximately equal ripple, the net effect is that the ripple observed by a connecting load (e.g. battery) is negligible.

To achieve synchronization between multiple devices, a novel communication protocol is proposed which utilises the data bus 103 to synchronize pseudorandom variation of the PWM signal Sm across multiple devices. Such synchronization may be performed in various ways.

In one example, the main device 106 may communicate a phase offset with respect to a transmitted sync pulse using payload information in a synchronization frame transmitted over the data line 104 to the one or more secondary devices 108, 110, 112. In doing so, secondary device 108, 110, 112 can account for variations in duration of the modulated signal Sm due to pseudorandom variation in period of the modulated signal Sm. A disadvantage of this approach is that it may require an increase in bandwidth for communicating the required offset from the main device 108 to the one or more secondary devices 108, 110, 112.

To avoid the need for additional bandwidth for communicating offset, in another example, the main device 106 may adjust a length of a synchronization packet transmitted to the one or more secondary devices 108, 110, 112 so that each data packet aligns with PWM adjusted frames, as will now be described.

As noted above, each of the main and secondary devices 106, 108, 110, 112 may be implemented as the device 200 shown in FIG. 2. Thus, each device 106, 108, 110, 112 may comprise a respective PRNG 302, which may be implemented as an LFSR. The PRNG 302 in each of the devices 106, 108, 110, 112 may be implemented so as to output the same pseudorandom sequence. For example, each PRNG 302 may be substantially identical to all other PRNG(s) 302 in the system 100. Each of the PRNGs 302 may be clocked by the (common) interface clock CLK which is communicated over the clock line 102. Each of the PRNGs 302 may be synchronized over the data line 104. Such synchronization may be performed by each device 106, 108, 110, 112 resetting their respective PRNG 302 at the same time. In doing so, each device 106, 108, 110, 112 may implement a PRNG 302 which outputs a synchronized and identical sequence of pseudorandom numbers to the PRNG(s) 302 of the other devices.

The sequence output from each PRNG 302 can then be used by a respective device 106, 108, 110, 112 to control generation of the modulated signal Sm in synchrony with all other devices. In addition, each of the secondary devices 108, 110, 112 can use the output of their respective PRNG 302 to determine the length and alignment of synchronization packets received over the data line 104 from the main device 106.

FIG. 6 graphically illustrates an example synchronization frame 600. In this instance, the synchronization frame 600 is 24 bits long. As mentioned above, however, the length of a given synchronization frame may be varied to align with the length of the PWM signal Sm generated by respective devices 106, 108, 110, 112. For example, the synchronization frame may be 22 bits long, or 23 bits long, or 24 bits long. The length of the synchronization frame 600 may be defined by the number of space bits 602 of the frame 600. The space bits 602 may vary between none, 1 and 2 bits to provide the necessary variation in length of the synchronization frame 600 for alignment with variations in the PWM signal Sm. It will be appreciated that whilst in this example the frame 600 is between 22 and 24 bits long, frames of other lengths (and variations thereof) fall within the scope of the present disclosure.

The main device 106 may be configured to generate each synchronization frame 600 with a number of space bits 602 which corresponds to the PRN generated by its PRNG 302. Since each of the secondary devices 108, 110, 112 are running a synchronized PRNG 302 generating an identical number sequence, the secondary device 110, 112, 114 use the number generated by their respective PRNGs 302 to determine an expected length of the synchronization frame 600 being received over the data line 104, as will be explained in more detail below.

The synchronization frame 600 may further comprise a synchronization bit 604 which may be used by respective secondary devices 108, 110, 112 to clear or reset respective PRNGs 302 at the same time as each other and as the main device 108 clears or resets its PRNG 302. For example, on receipt of the synchronization bit 604, each of the secondary devices 108, 110, 112 may be configured to reset its respective PRNG 302, returning it to its first state. As an alternative to the providing the synchronization bit 604, synchronization data may be provided in other forms. For example, synchronization data may be encoded elsewhere in the synchronization frame 600. Additionally or alternatively, each of the main and secondary devices 106, 108, 110, 112 may be configured to initiate or reset its respective PRNG 302 upon receipt/transmission of a given number of frames from the main device 106 to the secondary devices 108, 110, 112.

The synchronization frame 600 may comprise one or more mode bits 606. The mode bits may define a mode of operation of each device 106, 108, 110, 112. For example, the mode bits may define the number of switching converters 208 that need to be active at a given moment. The mode bits 606 may define one or more phase offsets to be implemented in a multi-phase configuration. For example, the mode bits 606 may be define a phase offset to be implemented by each of the active switching converters 208. For example, one or more of the devices 106, 108, 110, 112 may be 90 degrees out of phase. For example, one or more of the devices 106, 108, 110, 112 may be 180 degrees out of phase. For example, one or more of the devices 106, 108, 110, 112 may be 270 degrees out of phase. In one example, if four switching converters are provided over the four devices 106, 108, 110, 112, with 90 degrees phase difference to each other, the mode bits 606 may define four phase offsets or 0, 90, 180 and 270.

The synchronization frame 600 may comprise one or more target current bits 608. The target current bits 608 may determine the target current required at the outputs of respective switching converters 208. Dividing this value by the number of active switch converters (as defined by the mode bits 606), provides each active device controller 204 with the current target for their respective switching converter(s) 208. Respective controllers 204 may then be configured to vary the duty cycle of respective switching converter(s) 208 to hi the target current defined by the target current bits 608.

The synchronization frame 600 may comprise one or more synchronization bits 610 at the beginning of the frame 600 to enable respective secondary device(s) 110, 112, 114 to read subsequent information in the frame 600.

The synchronization frame 600 may comprise one or more error detecting bits 612 which may be used by respective secondary device(s) 110, 112, 114 to determine one or more errors in a received frame. Such error detecting bits 612 may implement a cyclic redundancy check (CRC) or a similar error detection regime.

As noted above, the PRN output may be used to determine both the length of the synchronization frame 302 and the ramp peak PEAK of the ramp signal RAMP used to generate the modulated PWM signal Sm. For example, for a given device 200, two bits of the PRN output from the PRNG 302 may be used to define a length of the synchronization frame 600. The table below illustrates an example encoding regime where bits 1 and 0 of the PRN are used.

| PRN[1:0] | Sync Frame Length | PWM Ramp Peak |
|---|---|---|
| 2′b00 | 22 bits | 44 |
| 2′b01 | 23 bits | Mean value 46 |
| 2′b10 | 23 bits | Mean value 46 |
| 2′b11 | 24 bits | 48 |

Typically, the interface clock CLK will run at a much slower rate than the quantization clock. For example, if the quantization clock CLKq runs at 192 MHz, the interface clock CLKi may run at 24 MHz. In which case, a single Sync Frame transmission may last for four ramps of the ramp signal RAMP (i.e. two ramps up and two ramps down).

It can be seen from the above that two PRN codes define a synchronization frame length as 23 bits, one PRN code defines a frame length of 22 bits, and one PRN code defines a frame length of 24 bits. When the frame length is 23 bits, there may be multiple possible configurations of values of the ramp peak PEAK of the ramp signal RAMP. As such, a further two bits of the PRM output from the PRNG 302 may be used to define the behaviour of the PWM signal Sm when the length of the synchronization frame 600 is 23 bits long. The following table provides a non-limiting example of such encoding where bits 4, 3 and 2 of the PRN are used:

| PRN[4:2] | PWM Ramp Peak |
|---|---|
| 3′b000 | 46, 46, 46, 46 |
| 3′b001 | 47, 47, 45, 45 |
| 3′b010 | 47, 47, 45 ,45 |
| 3′b011 | 47, 47, 45 ,45 |
| 3′b100 | 45, 45, 47, 47 |
| 3′b101 | 45, 45, 47, 47 |
| 3′b110 | 45, 45, 47, 47 |
| 3′b111 | 48, 48, 44, 44 |

FIG. 7 is a timing diagram illustrating an implementation of the above encoding regime, showing the PRN, the synchronization frame clocks, and the PWM ramp count/peak. It can be seen that as the PRN changes, so too does the frame length and PWM ramp count in accordance with the above.

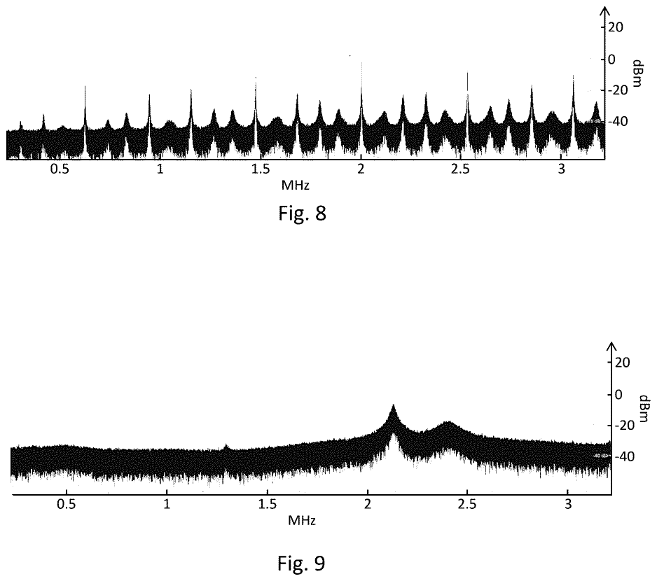

The effect of implementing synchronized spread spectrum modulated signal generation for multiple switching converters is illustrated in FIGS. 8 and 9.

FIG. 8 shows a frequency response of a PWM signal Sm with a fixed frequency of 2 MHz. It can be seen that the modulated signal Sm exhibits a large peak at 2 MHz. In contrast, FIG. 9 shows a frequency response of a PWM signal Sm with a varying frequency. It can be seen that the spectrum of the signal is distributed around 2.09 MHz with a lower overall peak.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog TM or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general-purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims As used herein, when two or more elements are referred to as “coupled” to one another, such term indicates that such two or more elements are in electrical, mechanical, or electromechanical communication, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim. Any reference numerals or labels in the claims shall not be construed so as to limit their scope.

1. A power converter system, comprising:
a main device;
one or more secondary devices, each comprising:
one or more switching converters; and
a signal generator configured to generate a modulated signal for controlling the one or more switching converters, wherein a period of the modulated signal is pseudo-randomly adjusted within a predetermined period range; and
a data bus comprising a data line for data transmission between the main device and the plurality of secondary devices, and a clock line for transmitting an interface clock signal;
wherein the main device is configured to transmit a synchronization frame to the plurality of secondary devices;
wherein each of the one or more secondary devices is configured to time align generation of the modulated signal in dependence on the synchronization frame.

2. The power converter system of claim 1, wherein the modulated signal is a pulse width modulated, PWM, signal, wherein the period is a switching period of the PWM signal.

3. The power converter system of claim 2, wherein:
each signal generator is configured to generate a PWM ramp signal,
the PWM signal is generated based on the PWM ramp signal, and
the signal generator is configured to pseudo-randomly vary a peak amplitude of the ramp signal within a predetermined peak range.

4. The power converter system of claim 3, wherein the PWM ramp signal comprises a triangular ramp or a sawtooth ramp.

5. The power converter system of claim 3, wherein an amplitude of the PWM ramp signal is increased during a ramp-up phase in steps at a quantization clock frequency, wherein the signal generator is configured to pseudo-randomly vary the duration of the ramp-up phase.

6. The power converter system of claim 5, wherein the quantization clock frequency is greater than a frequency of the interface clock.

7. The power converter system of claim 3, wherein the signal generator comprises:
a comparator, comprising:
a first input for receiving the PWM ramp signal;
a second input for receiving a PWM control signal; and
an output for outputting the PWM signal.

8. The power converter system of claim 1, wherein the synchronization frame comprises one or more synchronization bits, wherein each of the one or more secondary devices is configured to time align generation of the modulated signal in dependence on receipt of the one or more synchronization bits.

9. The power converter system of claim 1, wherein each of the one or more secondary devices is configured to time align generation of the modulated signal in response to receipt of the synchronization frame.

10. The power converter system of claim 1, wherein each signal generator comprises:
a pseudorandom number generator clocked by the interface clock signal, the pseudorandom number generator configured to generate a pseudorandom number.

11. The power converter system of claim 10, wherein each signal generator is configured to synchronously reset its respective pseudorandom number generator in response to receipt of synchronization data in the synchronization frame.

12. The power converter system of claim 10, wherein the pseudorandom number generator comprises a linear feedback shift register, LFSR.

13. The power converter system of claim 10, wherein the signal generator is configured to pseudo-randomly vary a period of the modulated signal based on the pseudorandom number.

14. The power converter of claim 10, wherein the one or more secondary device comprises a plurality of secondary devices, wherein respective pseudorandom number generators of the plurality of secondary devices are configured to output an identical sequence of pseudorandom numbers.

15. The power converter of claim 14, wherein the respective pseudorandom number generators of the plurality of secondary devices are substantially identical.

16. The power converter system of claim 10, wherein the main device comprises:
one or more main switching converters; and
a main signal generator configured to generate a main modulated signal for controlling the one or more main switching converters, wherein a period of the main modulated signal is pseudo-randomly adjusted within a predetermined period range, wherein the main signal generator comprises a main pseudorandom number generator, wherein the main pseudorandom number generator is configured to output an identical sequence of pseudorandom numbers to the pseudorandom number generators of each of the one or more secondary devices.

17. The power converter system of claim 10, wherein the main device comprises:
a main pseudorandom number generator, the main pseudorandom number generator configured to output an identical sequence of main pseudorandom numbers to the pseudorandom number generators of each of the one or more secondary devices.

18. The power converter system of claim 17, wherein a length of the synchronization frame is set based on the main pseudorandom number.

19. The power converter system of claim 15, wherein the main device comprises:
one or more main switching converters; and
a main signal generator configured to generate a main modulated signal for controlling the one or more main switching converters, wherein a period of the main modulated signal is pseudo-randomly adjusted within a predetermined period range.

20. The power converter system of claim 1, wherein a length of the synchronization frame is pseudo-randomly adjusted.

21. The power converter system of claim 1, wherein the synchronization frame comprises one or more target current bits, wherein the signal generator is configured to modulate the modulated signal based on the one or more target current bits.

22. The power converter system of claim 1, wherein the synchronization frame comprises one or more phase mode bits, wherein based on the one or more mode bits, the signal generator is configured to activate or deactivate the one or more switching converters and/or adapt a phase of the modulated signal.

23. (canceled)

24. The power converter system of claim 1, wherein the data bus is a serial data bus or a two-wire bus.

25. A main device configured to communication with a plurality of secondary devices via a data bus comprising a data line and a clock line;
wherein the main device is configured to communicate with each of the plurality of secondary devices using a unique secondary address associated with each respective secondary device,
wherein the main device is transmit a synchronization frame to the plurality of secondary devices, the synchronization frame used by each of the one or more secondary devices to time align generation of the modulated signal in dependence on the synchronization frame.

26. (canceled)

27. A secondary device configured to communicate with a main device via a data bus comprising a data line and a clock line, the secondary device comprising:
one or more secondary devices, each comprising:
one or more switching converters; and
a signal generator configured to generate a modulated signal for controlling the one or more switching converters, wherein a period of the modulated signal is pseudo-randomly adjusted within a predetermined period range;
the secondary device configured to:
receive, over the data line, a synchronization frame; and
time align generation of the modulated signal in dependence on the synchronization frame.

28. (canceled)

29. An electronic device, comprising the power converter system of claim 1.

30. (canceled)
